(19) United States
(12) Patent Application Publication
(10) Pub. No.: US 2023/0184851 A1
(43) Pub. Date: Jun. 15, 2023

(54) MAGNETIC POLE DETECTION CIRCUIT AND MOTOR CONTROL METHOD

(71) Applicants: INVENTEC APPLIANCES (PUDONG) CORPORATION, Shanghai (CN); INVENTEC APPLIANCES CORPORATION, New Taipei City (TW); INVENTEC APPLIANCES (SHANGHAI) CO. LTD., Shanghai (CN)

(72) Inventors: Ming-Tsan Lin, New Taipei City (TW); Zi-Xuan Huang, New Taipei City (TW)

(21) Appl. No.: 17/666,586

(22) Filed: Feb. 8, 2022

(30) Foreign Application Priority Data
Dec. 13, 2021 (CN) 202111519749.3

(51) Int. Cl. G01R 33/02; H02P 29/00

(52) U.S. Cl. CPC G01R 33/02; H02P 29/00

(57) ABSTRACT

A magnetic pole detection circuit includes a multi-phase voltage divider unit, a filter unit, a DC level compensation unit, an amplifying unit, and a hysteresis comparison unit. The multi-phase voltage divider unit is configured to detect a back electromotive force (EMF) signal of a multi-phase motor. The filter unit is configured to filter the back EMF signal to generate a filtered signal. The DC level compensation unit is configured to compensate a DC level of the filtered signal to generate a compensation signal. The amplifying unit is configured to amplify the compensation signal to generate an amplified signal. The hysteresis comparison unit is configured to generate a zero-crossing point signal according to the amplified signal and a reference signal. The zero-crossing point signal is adapted to control an excitation mode of the multi-phase motor.

### CROSS-REFERENCE TO RELATED APPLICATION

This non-provisional application claims priority under 35 U.S.C. § 119(a) to Patent Application No. 202111519749.3 filed in China, P. R. C. on Dec. 13, 2021, the entire contents of which are hereby incorporated by reference.

### BACKGROUND

### Technical Field

The present invention relates to magnetic pole detection of brushless DC motors, and in particular, to a magnetic pole detection circuit and a motor control method.

### Related Art

Traditionally, DC motors may be classified into brushed DC motors and brushless DC motors. The brushless DC motors are more popular with users due to advantages such as no carbon brush wear, no operation sparks, and high efficiency.

Generally, in order to enable a correct commutation of a brushless DC motor, a Hall sensor or a rotary encoder is usually used to detect a magnetic pole position of the motor. However, the configuration of the component such as the Hall sensor or the rotary encoder increases the manufacturing costs and requires additional wiring, making the reliability of the system easily reduced by factors such as disconnection or component failure.

In addition, the magnetic pole position of the motor is also detected by sensing a back electromotive force (EMF). However, the back EMF is susceptible to interference of a pulse wave modulation (switching) voltage. Moreover, when the motor runs at a low speed, the back EMF is small and difficult to detect.

### SUMMARY

The present invention provides a magnetic pole detection circuit. In an embodiment, the magnetic pole detection circuit includes a multi-phase voltage divider unit, a filter unit, a DC level compensation unit, an amplifying unit, and a hysteresis comparison unit. The multi-phase voltage divider unit is configured to detect a back EMF signal of a multi-phase motor. The filter unit is configured to filter the back EMF signal to generate a filtered signal. The DC level compensation unit is configured to compensate a DC level of the filtered signal to generate a compensation signal. The amplifying unit is configured to amplify the compensation signal to generate an amplified signal. The hysteresis comparison unit is configured to generate a zero-crossing point signal according to the amplified signal and a reference signal. The zero-crossing point signal is adapted to control an excitation mode of the multi-phase motor.

In some embodiments, the magnetic pole detection circuit further includes a motor controller. The motor controller is configured to control the excitation mode of the multi-phase motor according to the zero-crossing point signal.

In some embodiments, the motor controller switches the excitation mode of the multi-phase motor when the zero-crossing point signal is detected, and maintains the excitation mode of the multi-phase motor when the zero-crossing point signal is not detected.

In some embodiments, the DC level compensation unit is a digital-to-analog converter to dynamically compensate the DC level of the back EMF signal.

The present invention further provides a motor control method. In an embodiment, the motor control method includes: detecting a back EMF signal of a multi-phase motor; filtering the back EMF signal to generate a filtered signal; compensating a DC level of the filtered signal to generate a compensation signal; amplifying the compensation signal to generate an amplified signal; and generating a zero-crossing point signal according to the amplified signal and a reference signal. The zero-crossing point signal is adapted to control an excitation mode of the multi-phase motor.

In some embodiments, the motor control method further includes: controlling the excitation mode of the multi-phase motor according to the zero-crossing point signal.

In some embodiments, the step of controlling the excitation mode of the multi-phase motor according to the zero-crossing point signal includes: detecting the zero-crossing point signal; switching the excitation mode of the multi-phase motor when the zero-crossing point signal is detected; and maintaining the excitation mode of the multi-phase motor when the zero-crossing point signal is not detected.

In some embodiments, the step of compensating a DC level of the back EMF signal to generate a compensation signal is dynamically compensating the DC level of the back EMF signal by a digital-to-analog converter.

The present invention further provides a magnetic pole detection circuit. In an embodiment, the magnetic pole detection circuit includes a back EMF amplifying circuit and a hysteresis comparison circuit. The back EMF amplifying circuit is configured to receive a back EMF signal of a multi-phase motor and amplify an amplitude of the back EMF signal. The hysteresis comparison circuit is configured to receive a reference signal and the amplified back EMF signal. The hysteresis comparison circuit is configured to perform a hysteresis comparison on the reference signal and the amplified back EMF signal to avoid signal bounce due to switching noise, and generate a zero-crossing point signal based on a result of the hysteresis comparison. The zero-crossing point signal is adapted to control an excitation mode of the multi-phase motor.

In some embodiments, the magnetic pole detection circuit further includes a digital-to-analog conversion circuit. The digital-to-analog conversion circuit is configured to receive the back EMF signal and dynamically compensate a DC level of the back EMF signal, to avoid phase lag. The back EMF signal received by the back EMF amplifying circuit is the back EMF signal output after the dynamical compensation by the digital-to-analog conversion circuit.

In some embodiments, the magnetic pole detection circuit further includes a low-pass filter circuit. The low-pass filter circuit is configured to receive the back EMF signal, and perform low-pass filtering on the switching noise on the back EMF signal. The back EMF signal received by the digital-to-analog conversion circuit is the back EMF signal output after the low-pass filtering by the low-pass filter circuit.

In some embodiments, the magnetic pole detection circuit further includes a multi-phase voltage divider circuit. The multi-phase voltage divider circuit is coupled to the multi-phase motor. The multi-phase voltage divider circuit is configured to detect the multi-phase motor to generate the back EMF signal, and perform voltage division and filtering on the switching noise on the back EMF signal. The back EMF signal received by the low-pass filter circuit is the back EMF signal output after the voltage division and filtering by the multi-phase voltage divider circuit.

Detailed features and advantages of the present invention are described in detail in the following implementations, and the content of the implementations is sufficient for a person skilled in the art to understand and implement the technical content of the present invention. A person skilled in the art can easily understand the objectives and advantages related to the present invention according to the content disclosed in this specification, the claims and the drawings.

### BRIEF DESCRIPTION OF THE DRAWINGS

FIG. 1 is a schematic outline block diagram of a first embodiment of a magnetic pole detection circuit and a multi-phase motor;

FIG. 2 is a schematic outline circuit diagram of an embodiment of the magnetic pole detection circuit when detecting a back EMF signal of a phase of the multi-phase motor;

FIG. 3 is a schematic outline circuit diagram of an embodiment of a motor controller and the multi-phase motor;

FIG. 4 is a schematic outline block diagram of a second embodiment of the magnetic pole detection circuit and the multi-phase motor;

FIG. 5 is a schematic diagram of waveforms of an original back EMF signal, a filtered signal, and a DC level compensation signal;

FIG. 6 is a schematic diagram of waveforms of an actual back EMF voltage and a back EMF to simulated neutral point voltage after voltage division;

FIG. 7 is a schematic diagram of waveforms of a back EMF to ground voltage after voltage division, a voltage after back EMF filtering, and a zero-crossing point signal;

FIG. 8 is a schematic flowchart of an embodiment of a motor control method;

and

FIG. 9 is a schematic flowchart of an embodiment of step S06.

### DETAILED DESCRIPTION

To make the objectives, features, and advantages of the embodiments of the present invention more comprehensible, the following provides detailed descriptions with reference to the accompanying drawings.

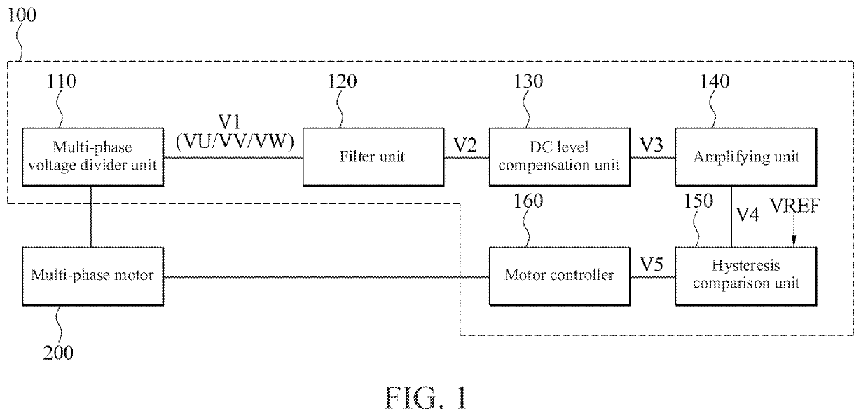

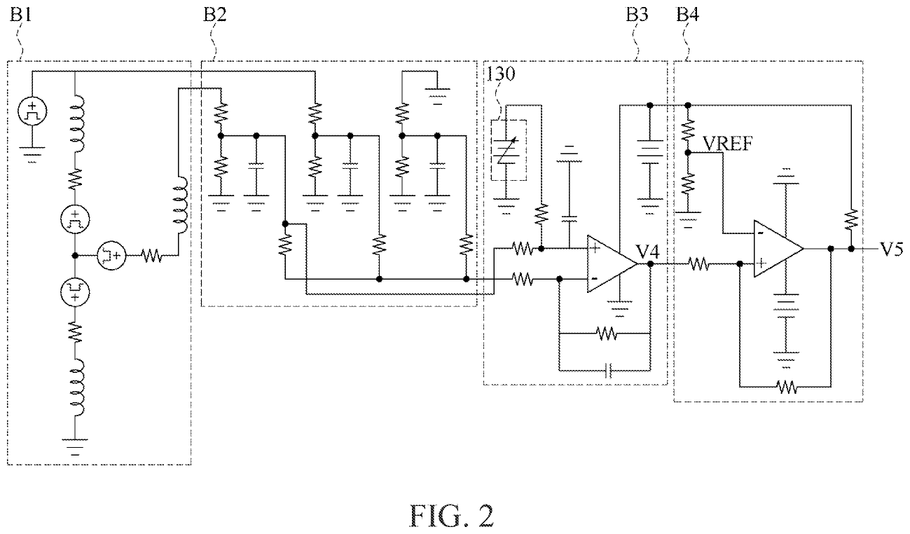

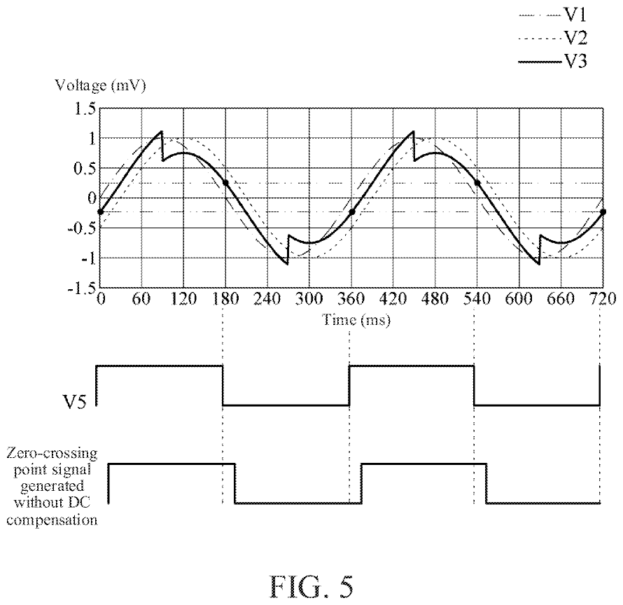

FIG. 1 is a schematic outline block diagram of a first embodiment of a magnetic pole detection circuit and a multi-phase motor, FIG. 2 is a schematic outline circuit diagram of an embodiment of the magnetic pole detection circuit when detecting a back EMF signal of a phase of the multi-phase motor, and FIG. 5 is a schematic diagram of waveforms of an original back EMF signal, a filtered signal, and a DC level compensation signal. Referring to FIG. 1, FIG. 2, and FIG. 5, a magnetic pole detection circuit 100 is adapted to a multi-phase motor 200. The multi-phase motor 200 is a brushless DC motor (BLDC motor), and the magnetic pole detection circuit 100 may be configured to detect a magnetic pole position of a rotor in the multi-phase motor 200, to precisely control the rotation speed of the multi-phase motor 200.

In some implementations, the multi-phase motor 200 may be, but not limited to, a two-phase or three-phase motor. Hereinafter, the description is made using an example in which the multi-phase motor 200 is a three-phase motor including three-phase coils. The three-phase coils of the multi-phase motor 200 may be configured in a Y-connection manner as shown in block B1 in FIG. 2. However, the present invention is not limited thereto, and the three-phase coils of the multi-phase motor 200 may also be configured in a delta connection manner.

In the first embodiment of the magnetic pole detection circuit 100, the magnetic pole detection circuit 100 includes a multi-phase voltage divider unit 110, a filter unit 120, a DC level compensation unit 130, an amplifying unit 140, and a hysteresis comparison unit 150. The multi-phase voltage divider unit 110 is coupled to the multi-phase motor 200, the filter unit 120 is coupled to the multi-phase voltage divider unit 110, the amplifying unit 140 is coupled to the filter unit 120 and the DC level compensation unit 130, and the hysteresis comparison unit 150 is coupled to the amplifying unit 140 and the multi-phase motor 200.

The multi-phase voltage divider unit 110 is configured to detect a back EMF signal V1 of the multi-phase motor 200. A waveform of the back EMF signal V1 may be as shown in FIG. 5. In FIG. 5, the horizontal axis is time in milliseconds (ms), and the vertical axis is voltage in millivolts (mV). In some embodiments, the multi-phase voltage divider unit 110 may include the same number of voltage dividers corresponding to the number of the phase coils of the multi-phase motor 200. For example, when the multi-phase motor 200 is a three-phase motor including three-phase coils, the multi-phase voltage divider unit 110 may include three voltage dividers as shown in block B2 in FIG. 2. Herein, the three voltage dividers of the multi-phase voltage divider unit 110 respectively correspond to one of the three-phase coils of the multi-phase motor 200, and the three voltage dividers may be respectively coupled to one end of the corresponding phase coil, to respectively obtain back EMF signals VU, VV, and VW after voltage division of two adjacent phase coils among the three-phase coils.

In some implementations, each voltage divider of the multi-phase voltage divider unit 110 may include two resistors connected in series as shown in block B2 in FIG. 2. However, the present invention is not limited thereto, and the multi-phase voltage divider unit 110 may alternatively be implemented by a buck converter.

The filter unit 120 is configured to filter the back EMF signal V1 obtained by the multi-phase voltage divider unit 110, to generate a filtered signal V2. The filtered signal V2 is the back EMF signal V1 obtained after switching noise is filtered by the filter unit 120. For example, when the back EMF signal V1 currently detected by the multi-phase voltage divider unit 110 is the back EMF signal VU, the filter unit 120 may filter the switching noise on the back EMF signal VU to generate the filtered signal V2. A waveform of the filtered signal V2 may be as shown in FIG. 5. It can be seen that compared to the back EMF signal V1, the phase of the filtered signal V2 has a phase delay.

In some implementations, the filter unit 120 may be a low-pass filter. In addition, in practice, the filter unit 120 may be further configured together with the multi-phase voltage divider unit 110. For example, a filter capacitor is further configured in each voltage divider of the multi-phase voltage divider unit 110 to form an RC filter as shown in block B2 in FIG. 2, but the present invention is not limited thereto.

In some embodiments, a transfer function of the filtered signal V2 may be as shown in Formula 1 below.

$$u ( t ) = \frac{{ω}_{C}}{\sqrt{{ω}^{2} + {ω}_{C}^{2}}} {V}_{m} sin ( ω t - {tan}^{- 1} \frac{ω}{{ω}_{C}} ) \qquad Formula 1$$

The DC level compensation unit 130 is configured to compensate a DC level of the filtered signal V2 to generate a compensation signal V3. The compensation signal V3 is the back EMF signal V1 after the filtering and DC level compensation. A waveform of the compensation signal V3 may be as shown in FIG. 5. It can be seen that the phase of the compensation signal V3 is substantially the same as that of the back EMF signal V1. Herein, the DC level compensation unit 130 is mainly configured to compensate the signal phase delay caused by the filter unit 120 and the hysteresis comparison unit 150. In some embodiments, the DC level compensation unit 130 may change the DC level of the filtered signal V2 in a dynamic compensation manner, to resolve the problem of phase lag. In some implementations, the DC level compensation unit 130 may be implemented using a digital-to-analog converter, but the present invention is not limited thereto.

In some embodiments, when the phase of t=0 is used as an example, a relationship between a compensation value of the DC level compensation unit 130 and a lower limit value of a hysteresis comparison width negative side of the hysteresis comparison unit 150 may be as shown in Formula 2 below. DAC refers to the compensation value of the DC level compensation unit 130, and-VZONE refers to the lower limit value of the hysteresis comparison width negative side.

$$- VZONE = DAC + \frac{{ω}_{C}}{\sqrt{{ω}^{2} + {ω}_{C}^{2}}} {V}_{m} sin ( - {tan}^{- 1} \frac{ω}{{ω}_{C}} ) \qquad Formula 2$$

$$DAC = - VZONE + \frac{{ω}_{C}}{\sqrt{{ω}^{2} + {ω}_{C}^{2}}} {V}_{m} \frac{ω}{\sqrt{{ω}^{2} + {ω}_{C}^{2}}}$$

$$DAC = - VZONE + \frac{{ω}_{C} ω}{{ω}^{2} + {ω}_{C}^{2}}$$

The amplifying unit 140 is configured to amplify an amplitude of the compensation signal V3 to generate an amplified signal V4. The amplified signal V4 is the back EMF signal V1 after the filtering, DC level compensation, and amplitude amplification, and the recognizable degree of a zero-crossing point thereof has been relatively improved. Herein, the amplifying unit 140 is mainly configured to compensate for the signal amplitude reduction caused by the filter unit 120 and to improve the signal detectability at a low speed.

In some embodiments, the amplifying unit 140 may have a positive input end, a negative input end, and an output end. The positive input end of the amplifying unit 140 is coupled to the filter unit 120 and the DC level compensation unit 130, to receive the compensation signal V3 generated after the filtering and DC level compensation. The negative input end of the amplifying unit 140 may be coupled to its output end through a resistor, and the amplifying unit 140 outputs the amplified signal V4 through its output end.

In some implementations, the amplifying unit 140 may be implemented using an operational amplifier, but the present invention is not limited thereto. In addition, a circuit implementation of the DC level compensation unit 130 and the amplifying unit 140 may be as shown in block B3 in FIG. 2, but the present invention is not limited thereto.

The hysteresis comparison unit 150 is configured to generate a zero-crossing point signal V5 according to the amplified signal V4 and a reference signal VREF. The generation of the zero-crossing point signal V5 by hysteresis comparison can avoid signal bounce due to slight switching noise. A waveform of the zero-crossing point signal V5 may be as shown in FIG. 5. It can be seen that when the compensation signal V3 reaches its hysteresis upper limit (for example, +0.25 mV) or its hysteresis lower limit (for example, −0.25 mV), the hysteresis comparison unit 150 causes the output zero-crossing point signal V5 to perform transition. In addition, it can be seen that if the hysteresis comparison unit 150 generates the zero-crossing point signal according to the back EMF signal without DC compensation (that is, the filtered signal V2) and the reference signal VREF, the zero-crossing point signal generated at this time has a problem of phase delay.

In some embodiments, as shown in block B4 in FIG. 2, the hysteresis comparison unit 150 may have a positive input end, a negative input end, and an output end. The positive input end of the hysteresis comparison unit 150 is coupled to the output end of the amplifying unit 140 to receive the amplified signal V4, and may be further coupled to its output end through a resistor. The negative input end of the hysteresis comparison unit 150 is configured to receive the reference signal VREF, and the hysteresis comparison unit 150 may perform the hysteresis comparison according to the amplified signal V4 and the reference signal VREF to output the zero-crossing point signal V5 through its output end.

In some implementations, the hysteresis comparison unit 150 may be implemented using an operational amplifier, but the present invention is not limited thereto. In addition, the reference signal VREF may have a fixed voltage, and for example, the voltage value thereof may be, but not limited to, 1 volt or 1.65 volts.

In some embodiments, the magnetic pole detection circuit 100 further includes a motor controller 160. The motor controller 160 is coupled to the output end of the hysteresis comparison unit 150 and the multi-phase motor 200. The motor controller 160 is configured to learn a magnetic pole position of a rotor in the multi-phase motor 200 according to the zero-crossing point signal V5, and may control an excitation mode of the multi-phase motor 200 according to the zero-crossing point signal V5.

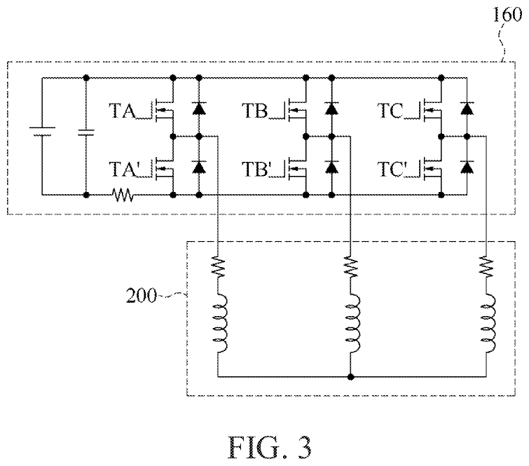

FIG. 3 is a schematic outline circuit diagram of an embodiment of a motor controller and the multi-phase motor. Referring to FIG. 1 to FIG. 3, in some implementations, a circuit implementation of the motor controller 160 and the multi-phase motor 200 may be as shown in FIG. 3, but the present invention is not limited thereto. Herein, the motor controller 160 may be a three-phase inverter mainly including six transistors, and the transistors are respectively controlled by corresponding control signals TA, TA′, TB, TB′, TC, and TC′. Levels of the control signals TA, TA′, TB, TB′, TC, and TC′ may correspondingly change according to the zero-crossing point signal V5.

When detecting the zero-crossing point signal V5, the motor controller 160 switches the excitation mode of the multi-phase motor 200 (that is, excites the next phase coil). When not detecting the zero-crossing point signal V5, the motor controller 160 maintains the current excitation mode of the multi-phase motor 200. For example, assuming that the current levels of the control signals TA, TA′, TB, TB′, TC, and TC′ are logic ‘1’, logic ‘0’, logic ‘0’, logic ‘1’, logic ‘0’, and logic ‘0’ respectively, when detecting the zero-crossing point signal V5, the motor controller 160 may respectively switch the levels of the control signals TA, TA′, TB, TB′, TC, and TC′ to logic ‘1’, logic ‘0’, logic ‘0’, logic ‘0’, logic ‘0’, and logic ‘1’, to switch the excitation mode of the multi-phase motor 200. Conversely, when not detecting the zero-crossing point signal V5, the motor controller 160 maintains the original values of the levels of the control signals TA, TA′, TB, TB′, TC, and TC′.

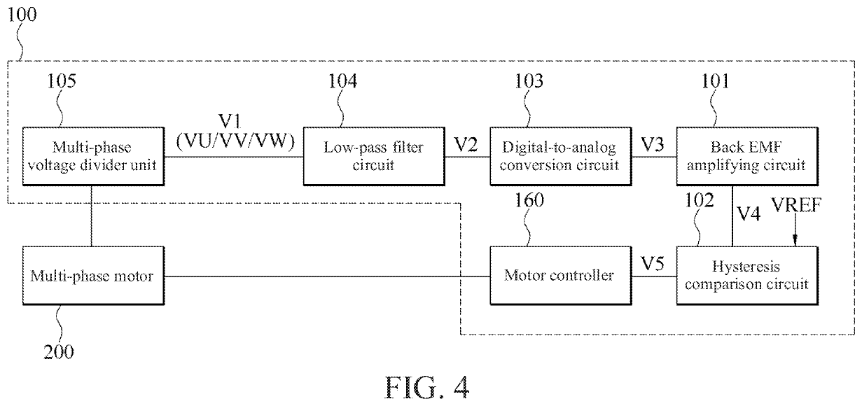

FIG. 4 is a schematic outline block diagram of a second embodiment of the magnetic pole detection circuit and the multi-phase motor; Referring to FIG. 4, in the second embodiment of the magnetic pole detection circuit 100, the magnetic pole detection circuit 100 includes a back EMF amplifying circuit 101 and a hysteresis comparison circuit 102, and the back EMF amplifying circuit 101 is coupled to the hysteresis comparison circuit 102. In addition, the magnetic pole detection circuit 100 may further include a digital-to-analog conversion circuit 103, a low-pass filter circuit 104, a multi-phase voltage divider circuit 105, and the motor controller 160. The multi-phase voltage divider circuit 105 is coupled to the multi-phase motor 200, the low-pass filter circuit 104 is coupled to the multi-phase voltage divider circuit 105, the digital-to-analog conversion circuit 103 is coupled to the back EMF amplifying circuit 101, and the hysteresis comparison circuit 102 is coupled to the motor controller 160.

The multi-phase voltage divider circuit 105 is configured to detect the multi-phase motor 200 to generate the back EMF signal V1, and perform voltage division and filtering on the switching noise on the back EMF signal caused by a PWM voltage for driving the multi-phase motor 200. Herein, the back EMF signal V1 still includes high-frequency switching noise after the voltage division and filtering.

The low-pass filter circuit 104 is configured to receive the back EMF signal V1 output after the voltage division and filtering by the multi-phase voltage divider circuit 105, and perform low-pass filtering on the switching noise on the back EMF signal V1. Herein, in order to avoid excessive phase delay, the low-pass filter circuit 104 does not completely filter out the switching noise on the back EMF signal V1. In addition, the back EMF signal V1 after the low-pass filtering by the low-pass filter circuit 104 (that is, the above filtered signal V2) has problems of amplitude reduction and phase lag. Moreover, because the filtered back EMF signal V1 still includes the high-frequency switching noise, the zero-crossing point signal V5 is likely to have a transition bounce problem. However, these problems can be resolved by components described later, to generate the zero-crossing point signal V5 that can be used to precisely control the rotation speed of the multi-phase motor 200.

The digital-to-analog conversion circuit 103 is configured to receive the back EMF signal V1 output after the low-pass filtering by the low-pass filter circuit 104 (that is, the above filtered signal V2), and dynamically compensate the DC level of the back EMF signal V1, to compensate for the phase lag caused by the low-pass filter circuit 104 and the hysteresis comparison circuit 102 described later.

The back EMF amplifying circuit 101 is configured to receive the back EMF signal V1 output after the dynamic compensation by the digital-to-analog conversion circuit 103 (that is, the above compensation signal V3), and amplify the amplitude of the back EMF signal V1, to compensate for the signal amplitude reduction caused by the low-pass filter circuit 104 and improve the signal detectability at a low speed.

The hysteresis comparison circuit 102 is configured to receive the reference signal VREF and the back EMF signal V1 after the amplitude amplification by the back EMF amplifying circuit 101 (that is, the above amplified signal V4). The hysteresis comparison circuit 102 may perform hysteresis comparison between the reference signal VREF and the back EMF signal V1 after the amplitude amplification, and generate the zero-crossing point signal V5 to the motor controller 160 according to a result of the hysteresis comparison. In this way, the signal bounce of the zero-crossing point signal V5 due to the slight switching noise on the back EMF signal V1 can be avoided. Although the hysteresis comparison circuit 102 worsens the signal delay, this has been correspondingly compensated by the above digital-to-analog conversion circuit 103.

In some embodiments, the circuit structure of the back EMF amplifying circuit 101 may be substantially the same as that of the above amplifying unit 140, the circuit structure of the hysteresis comparison circuit 102 may be substantially the same as that of the above hysteresis comparison unit 150, the circuit structure of the digital-to-analog conversion circuit 103 may be substantially the same as that of the above DC level compensation unit 130, the circuit structure of the low-pass filter circuit 104 may be substantially the same as that of the above filter unit 120, and the circuit structure of the multi-phase voltage divider circuit 105 may be substantially the same as that of the above multi-phase voltage divider unit 110. Therefore, detailed implementations thereof are not be repeated herein.

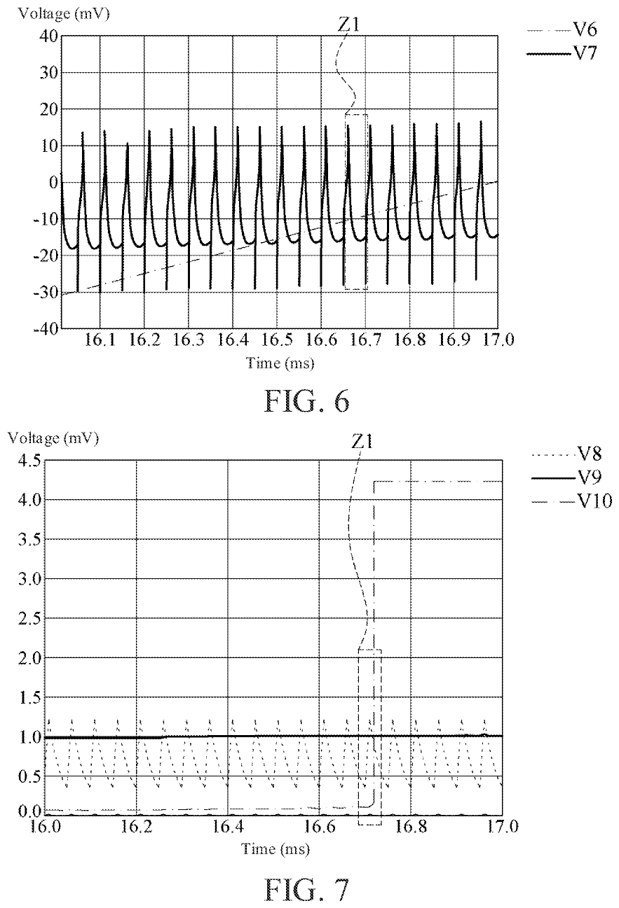

FIG. 6 is a schematic diagram of waveforms of an actual back EMF voltage and a back EMF to simulated neutral point voltage after voltage division, and FIG. 7 is a schematic diagram of waveforms of a back EMF to ground voltage after voltage division, a voltage after back EMF filtering, and a zero-crossing point signal. In some embodiments, waveforms of an actual back EMF voltage V6 obtained after simulation by the magnetic pole detection circuit 100 according to an embodiment and a back EMF to simulated neutral point voltage V7 after voltage division may be as shown in FIG. 6, and waveforms of an obtained back EMF to ground voltage V8 after voltage division, a voltage V9 after back EMF filtering, and a zero-crossing point signal V10 may be as shown in FIG. 7. The horizontal axis is time in ms, the vertical axis is voltage in mV, and the imaginary frame is a zero-crossing point Z1. As shown in FIG. 6, between 16 ms and 17 ms, the actual back EMF voltage V6 gradually decreases from −31 mV to 0 as time increases. The back EMF to simulated neutral point voltage V7 after voltage division jumps between about 15 mV and −30 mV. As shown in FIG. 7, between 16 ms and 17 ms, the back EMF to ground voltage V8 after voltage division jumps between about 0.3 mV and 1.3 mV. The voltage V9 after back EMF filtering is about 1 mV. The zero-crossing point signal V10 has a transition at the zero-crossing point Z1.

In summary, by the zero-crossing point signal V5 with a correct commutation timing, the magnetic pole detection circuit 100 of the present invention can precisely control the rotation speed of the multi-phase motor 200. In addition, because the magnetic pole detection circuit 100 of the present invention can correctly feedback the magnetic pole position at both high and low speeds, the multi-phase motor 200 can have a large torque output at both high and low speeds, which expands the speed control range of the multi-phase motor 200. Furthermore, with the expansion of the speed control range of the multi-phase motor 200, the applicable range of the multi-phase motor 200 is also wider. For example, the multi-phase motor 200 controlled by the magnetic pole detection circuit 100 of the present invention may be applied to a continuous positive pressure respirator that needs to output high torque at a low speed, an electric pruning machine having a wide speed control range to provide different rotation speeds in response to different cutting situations, and other machines.

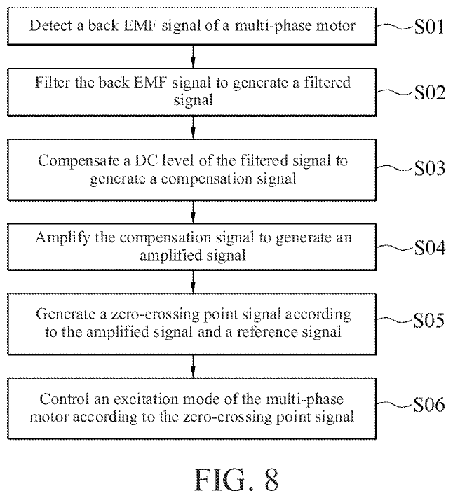

The magnetic pole detection circuit 100 of any embodiment can perform a motor control method of any embodiment, to precisely control the rotation speed of the multi-phase motor 200. Hereinafter, the description is made using the magnetic pole detection circuit 100 of the first embodiment as an example. FIG. 8 is a schematic flowchart of an embodiment of a motor control method. Referring to FIG. 1 to FIG. 8, in an embodiment of the motor control method, the magnetic pole detection circuit 100 may use the multi-phase voltage divider unit 110 to detect the back EMF signal V1 of the multi-phase motor 200 (step S01). Then, the magnetic pole detection circuit 100 uses the filter unit 120 to filter the back EMF signal V1, to generate the filtered signal V2 (step S02). Next, the magnetic pole detection circuit 100 may use the DC level compensation unit 130 to compensate the DC level of the filtered signal V2 to generate the compensation signal V3 (step S03), and use the amplifying unit 140 to amplify the amplitude of the compensation signal V3 to generate the amplified signal V4 (step S04). Then, the magnetic pole detection circuit 100 may use the hysteresis comparison unit 150 to generate, according to the amplified signal V4 and the reference signal VREF, the zero-crossing point signal V5 adapted to control the excitation mode of the multi-phase motor 200 (step S05).

In an embodiment of the motor control method, the magnetic pole detection circuit 100 may further use the motor controller 160 to control the excitation mode of the multi-phase motor 200 according to the zero-crossing point signal V5 (step S06). Then, the magnetic pole detection circuit 100 may return to step S01 to perform the motor control method again.

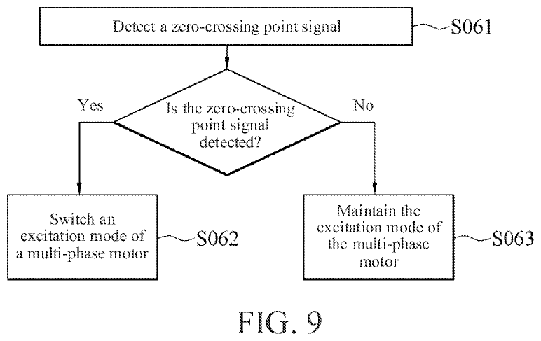

FIG. 9 is a schematic flowchart of an embodiment of step S06. Referring to FIG. 1 to FIG. 9, in an embodiment of step S06, the magnetic pole detection circuit 100 may use the motor controller 160 to detect the zero-crossing point signal V5 at the output end of the hysteresis comparison unit 150 (step S061). When the zero-crossing point signal V5 is detected, the magnetic pole detection circuit 100 may use the motor controller 160 to switch the excitation mode of the multi-phase motor 200 according to the level of the zero-crossing point signal V5 (step S062). When the zero-crossing point signal V5 is not detected, the magnetic pole detection circuit 100 uses the motor controller 160 to maintain the current excitation mode of the multi-phase motor 200 (step S063).

In summary, in the magnetic pole detection circuit and the motor control method of the embodiments of the present invention, the amplitude of the back EMF signal is amplified by the amplifying unit or the back EMF amplifying circuit, to improve the signal detectability at a low speed and make the magnetic pole detection circuit applicable to occasions where the motor is running at a low speed. Moreover, the zero-crossing point signal is generated by performing the hysteresis comparison according to the back EMF signal and the reference signal by the hysteresis comparison unit or the hysteresis comparison circuit, to avoid the transition bounce of the zero-crossing point signal caused by the slight switching noise. In addition, in the magnetic pole detection circuit and the motor control method of the embodiments of the present invention, the DC level of the back EMF signal is changed by the DC level compensation unit or the digital-to-analog converter, to compensate for the signal phase delay. In this way, the magnetic pole detection circuit and the motor control method of the embodiments of the present invention can precisely control the rotation speed of the multi-phase motor by the zero-crossing point signal with a correct commutation timing. In addition, the magnetic pole detection circuit and the motor control method of the embodiments of the present invention can correctly feedback the magnetic pole position at both high and low speeds, so that the multi-phase motor can have a large torque output at both high and low speeds, thereby expanding the speed control range of the multi-phase motor and the applicable range of the multi-phase motor. Furthermore, the magnetic pole detection circuit and the motor control method of the embodiments of the present invention do not need to use a Hall sensor or a rotary encoder to detect the magnetic pole position of the rotor, so that the costs of the driver can be reduced.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A magnetic pole detection circuit, comprising:
a multi-phase voltage divider unit, configured to detect a back electromotive force (EMF) signal of a multi-phase motor;
a filter unit, configured to filter the back EMF signal to generate a filtered signal;
a DC level compensation unit, configured to compensate a DC level of the filtered signal to generate a compensation signal;
an amplifying unit, configured to amplify the compensation signal to generate an amplified signal; and
a hysteresis comparison unit, configured to generate a zero-crossing point signal according to the amplified signal and a reference signal, wherein the zero-crossing point signal is adapted to control an excitation mode of the multi-phase motor.

2. The magnetic pole detection circuit according to claim 1, further comprising:
a motor controller, configured to control the excitation mode of the multi-phase motor according to the zero-crossing point signal.

3. The magnetic pole detection circuit according to claim 2, wherein the motor controller switches the excitation mode of the multi-phase motor when the zero-crossing point signal is detected, and maintains the excitation mode of the multi-phase motor when the zero-crossing point signal is not detected.

4. The magnetic pole detection circuit according to claim 1, wherein the DC level compensation unit is a digital-to-analog converter to dynamically compensate the DC level of the back EMF signal.

5. A motor control method, comprising:
detecting a back EMF signal of a multi-phase motor;
filtering the back EMF signal to generate a filtered signal;
compensating a DC level of the filtered signal to generate a compensation signal;
amplifying the compensation signal to generate an amplified signal; and
generating a zero-crossing point signal according to the amplified signal and a reference signal, wherein the zero-crossing point signal is adapted to control an excitation mode of the multi-phase motor.

6. The motor control method according to claim 5, further comprising:
controlling the excitation mode of the multi-phase motor according to the zero-crossing point signal.

7. The motor control method according to claim 6, wherein the step of controlling the excitation mode of the multi-phase motor according to the zero-crossing point signal comprises:
detecting the zero-crossing point signal;
switching the excitation mode of the multi-phase motor when the zero-crossing point signal is detected; and
maintaining the excitation mode of the multi-phase motor when the zero-crossing point signal is not detected.

8. The motor control method according to claim 5, wherein the step of compensating a DC level of the back EMF signal to generate a compensation signal is dynamically compensating the DC level of the back EMF signal by a digital-to-analog converter.

9. A magnetic pole detection circuit, comprising:
a back EMF amplifying circuit, configured to receive a back EMF signal of a multi-phase motor and amplify an amplitude of the back EMF signal; and
a hysteresis comparison circuit, configured to receive a reference signal and the amplified back EMF signal, wherein the hysteresis comparison circuit is configured to perform a hysteresis comparison on the reference signal and the amplified back EMF signal to avoid signal bounce due to switching noise, and generate a zero-crossing point signal based on a result of the hysteresis comparison, wherein the zero-crossing point signal is adapted to control an excitation mode of the multi-phase motor.

10. The magnetic pole detection circuit according to claim 9, further comprising:
a digital-to-analog conversion circuit, configured to receive the back EMF signal and dynamically compensate a DC level of the back EMF signal, to avoid phase lag, wherein the back EMF signal received by the back EMF amplifying circuit is the back EMF signal output after the dynamical compensation by the digital-to-analog conversion circuit.

11. The magnetic pole detection circuit according to claim 10, further comprising:
a low-pass filter circuit, configured to receive the back EMF signal, and perform low-pass filtering on the switching noise on the back EMF signal, wherein the back EMF signal received by the digital-to-analog conversion circuit is the back EMF signal output after the low-pass filtering by the low-pass filter circuit.

12. The magnetic pole detection circuit according to claim 11, further comprising:
a multi-phase voltage divider circuit, coupled to the multi-phase motor, wherein the multi-phase voltage divider circuit is configured to detect the multi-phase motor to generate the back EMF signal, and perform voltage division and filtering on the switching noise on the back EMF signal, wherein the back EMF signal received by the low-pass filter circuit is the back EMF signal output after the voltage division and filtering by the multi-phase voltage divider circuit.

13. The magnetic pole detection circuit according to claim 9, further comprising:
a motor controller, configured to receive the zero-crossing point signal, and control the excitation mode of the multi-phase motor according to the zero-crossing point signal.

14. The magnetic pole detection circuit according to claim 13, wherein the motor controller switches the excitation mode of the multi-phase motor when the zero-crossing point signal is detected, and maintains the excitation mode of the multi-phase motor when the zero-crossing point signal is not detected.
